(19) United States
(12) Patent Application Publication
(10) Pub. No.: US 2025/0369113 A1
(43) Pub. Date: Dec. 4, 2025

(54) NESTED-LOOP ATOMIC LAYER DEPOSITION WITH INHIBITION AND/OR ETCH

(71) Applicant: Applied Materials, Inc., Santa Clara, CA (US)

(72) Inventors: Sukrant Dhawan, Santa Clara, CA (US); Bhaskar Soman, San Jose, CA (US); Supriya Ghosh, San Jose, CA (US); Susmit Singha Roy, Campbell, CA (US); Akhil Singhal, Portland, OR (US)

(73) Assignee: Applied Materials, Inc., Santa Clara, CA (US)

(21) Appl. No.: 18/732,353

(22) Filed: Jun. 3, 2024

(51) Int. Cl. C23C 16/455; C23C 16/40; C23C 16/44; C23C 16/56

(52) U.S. Cl. CPC C23C 16/45553; C23C 16/401; C23C 16/4408; C23C 16/45536; C23C 16/56

(57) ABSTRACT

Exemplary methods of semiconductor processing may include i) performing an inhibition operation on a substrate disposed within a processing region of a semiconductor processing chamber. The substrate may define one or more features characterized by an aspect ratio of greater than or about 30:1. The methods may include ii) performing a silicon-containing atomic layer deposition (ALD) process. The silicon-containing ALD process may deposit a silicon-containing material in the one or more features. The methods may include iii) etching a portion of the silicon-containing material from an upper portion of the one or more features. The methods may include iv) repeating operations i) through iii) for a plurality of cycles.

### TECHNICAL FIELD

The present technology relates to methods and components for semiconductor processing. More specifically, the present technology relates to systems and methods for depositing silicon-containing materials with reduced seam and/or void presence.

### BACKGROUND

Integrated circuits are made possible by processes which produce intricately patterned material layers on substrate surfaces. Producing patterned material on a substrate requires controlled methods of formation and removal of exposed material. As device sizes continue to shrink, features within the integrated circuits may get smaller and aspect ratios of structures may grow, and maintaining dimensions of these structures during processing operations may be challenged. Some processing may result in seams or voids in the materials that may result in unwanted and undesirable effects in further processing. Developing materials that can control seam or void formation may become more difficult.

Thus, there is a need for improved systems and methods that can be used to produce high quality devices and structures. These and other needs are addressed by the present technology.

### SUMMARY

Exemplary methods of semiconductor processing may include i) performing an inhibition operation on a substrate disposed within a processing region of a semiconductor processing chamber. The substrate may define one or more features characterized by an aspect ratio of greater than or about 30:1. The methods may include ii) performing a silicon-containing atomic layer deposition (ALD) process. The silicon-containing ALD process may deposit a silicon-containing material in the one or more features. The methods may include iii) etching a portion of the silicon-containing material from an upper portion of the one or more features. The methods may include iv) repeating operations i) through iii) for a plurality of cycles.

In some embodiments, the one or more features may be characterized by a width of less than or about 250 nm. The one or more features may be characterized by a depth of greater than or about 1 μm. The one or more features may be characterized by an aspect ratio of greater than or about 100:1. The inhibition operation may include contacting the substrate with a nitrogen-containing precursor. The nitrogen-containing precursor may be or include ammonia (NH₃). The methods may include forming plasma effluents of the nitrogen-containing precursor. The inhibition operation may reduce deposition of silicon-containing material at an upper portion of the one or more features. The silicon-containing ALD process may include ii-a) depositing a silicon-containing material on the substrate, ii-b) purging the processing region after operation ii-a, ii-c) exposing the silicon-containing material to an oxygen-containing precursor to convert the silicon-containing material to a silicon-and-oxygen-containing material, and ii-d) purging the processing region after operation ii-c. The silicon-containing ALD process may be plasma-enhanced. The etching may prevent closing of the one or more features. The silicon-containing material may be seam-free and void-free. The as-deposited silicon-containing material may be characterized by a conformality of greater than or about 120%.

Some embodiments of the present technology may encompass semiconductor processing methods. The methods may include providing a nitrogen-containing precursor to a processing region of a semiconductor processing chamber. A substrate may be housed within the processing region. The substrate may define one or more features characterized by an aspect ratio of greater than or about 30:1. The methods may include contacting the substrate with the nitrogen-containing precursor. The contacting may form a nitrogen-containing material on an upper portion of the one or more features. The methods may include performing a silicon-containing atomic layer deposition (ALD) process. The silicon-containing ALD process may deposit a silicon-containing material in the one or more features. The methods may include providing an etchant precursor to the processing region. The methods may include contacting the substrate with the etchant precursor. The contacting may etch a portion of the silicon-containing material from the upper portion of the one or more features.

In some embodiments, the nitrogen-containing precursor may be or include ammonia (NH₃). The etchant precursor may be or include a fluorine-containing precursor. The methods may include forming plasma effluents of the etchant precursor. The methods may include repeating the performing the silicon-containing ALD process, the contacting the substrate with the etchant precursor, and optionally the contacting the substrate with the nitrogen-containing precursor for a plurality of cycles.

Some embodiments of the present technology may encompass semiconductor processing methods. The methods may include providing a nitrogen-containing precursor to a processing region of a semiconductor processing chamber. A substrate may be housed within the processing region. The substrate may define one or more features characterized by an aspect ratio of greater than or about 30:1. The methods may include forming plasma effluents of the nitrogen-containing precursor. The methods may include contacting the substrate with the plasma effluents of the nitrogen-containing precursor. The contacting may form a nitrogen-containing material on an upper portion of the one or more features. The methods may include performing a silicon-containing atomic layer deposition (ALD) process. The silicon-containing ALD process may include depositing a silicon-containing material on the substrate, purging the processing region, exposing the silicon-containing material to an oxygen-containing precursor to convert the silicon-containing material to a silicon-and-oxygen-containing material, and purging the processing region. The methods may include providing an etchant precursor to the processing region. The methods may include contacting the substrate with the etchant precursor. The contacting may etch a portion of the silicon-containing material from the upper portion of the one or more features.

In some embodiments, the nitrogen-containing precursor may be or include ammonia (NH₃).

Such technology may provide numerous benefits over conventional systems and techniques. For example, embodiments of the present technology may control deposition of material for gap fill applications. Through intermittent inhibition and/or etching during the deposition, the present technology may deposit material in features in a bottom-up, zipper-like fashion with reduced and/or prevented formation of seams and/or voids. These and other embodiments, along with many of their advantages and features, are described in more detail in conjunction with the below description and attached figures.

### BRIEF DESCRIPTION OF THE DRA WINGS

A further understanding of the nature and advantages of the disclosed technology may be realized by reference to the remaining portions of the specification and the drawings.

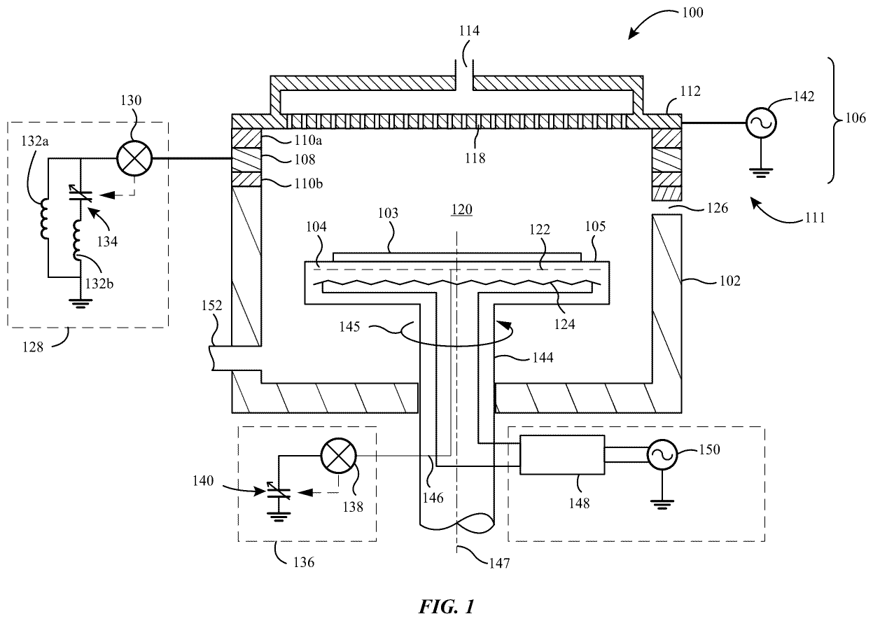

FIG. 1 shows a schematic cross-sectional view of an exemplary plasma system according to some embodiments of the present technology.

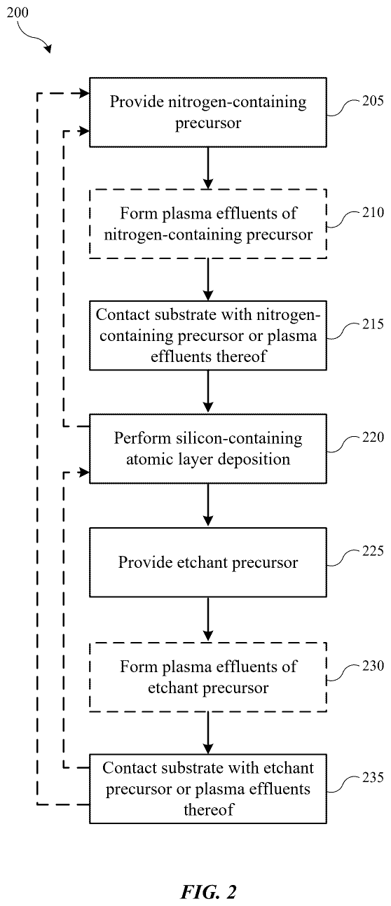

FIG. 2 shows operations in a semiconductor processing method according to some embodiments of the present technology.

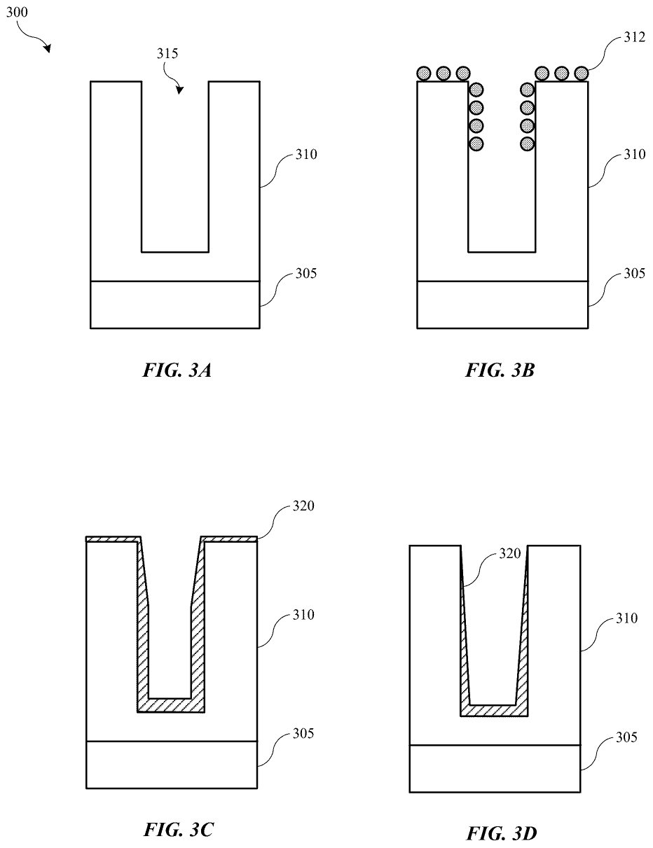

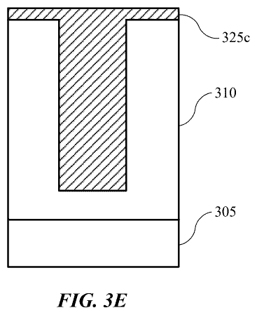

FIGS. 3A-3E show exemplary schematic cross-sectional structures in which material layers are included and produced according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As device sizes continue to shrink, many material layers may be reduced in thickness and size to scale devices. Features inside semiconductor structures may be reduced in size, and aspect ratios of the features may increase. As the aspect ratios of the features increase, atomic layer deposition (ALD) processes may produce scams or voids within the feature.

Conventional technologies have struggled to produce films to fill high aspect ratio features in the underlying structures where scam or void formation is controlled. Deposition of silicon-containing materials on the underlying structures containing the high aspect ratio trenches may be incomplete. The conformal fill operation may allow the feature to seal near the top of the feature prior to fill within the feature, as well as to produce a seam up the middle of the feature, which can extend to the top of the structure. In some production, where a polishing operation may subsequently occur, the removal may cause the seam to be exposed, which may provide access within the feature. This may allow oxidation of the material once exposed to atmosphere, as well as incorporation of slurry or other materials along the seam. Accordingly, many conventional technologies have been limited in the ability to prevent structural flaws in the final devices.

The present technology overcomes these issues by intermittently performing an inhibition operation and etching operation. The inhibition operation may reduce an amount of deposition at upper portions of features being gap filled. However, the inhibition may not prevent deposition entirely. Therefore, after an amount of deposition of the gap fill material, an upper portion of the gap fill material at an upper portion of the features being gap filled may pinch or seal off. This pinching or sealing may prevent additional deposition within the feature. Due to the conformal deposition of the gap fill material, seams and/or voids may be present in the silicon-containing material. To remove gap fill material at an upper portion of the features, at etching operation may be performed to open up the feature. Subsequent iterations of the inhibition and/or deposition may be performed to deposit material in the previous seams and/or voids. The present technology may perform multiple iterations of the inhibition, deposition, and etching to completely fill the features with gap fill material. Some cycles of the present technology may include only the inhibition and deposition while others may include only the deposition and etching.

After describing general aspects of a chamber according to some embodiments of the present technology in which gap filling operations discussed below may be performed, specific methodology may be discussed. It is to be understood that the present technology is not intended to be limited to the specific films, chambers or processes discussed, as the techniques described may be used to improve a number of film formation processes, and may be applicable to a variety of processing chambers and operations.

FIG. 1 shows a cross-sectional view of an exemplary semiconductor processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers according to some embodiments of the present technology, although it is to be understood that the methods may similarly be performed in any chamber within which film formation may occur. The semiconductor processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support 104 during processing. The substrate support 104 may be rotatable, as indicated by the arrow 145, along an axis 147, where a shaft 144 of the substrate support 104 may be located. Alternatively, the substrate support 104 may be lifted up to rotate as necessary during a deposition cycle and/or a densification operation.

A plasma profile modulator 111 may be disposed in the semiconductor processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular or ring-like member, and may be a ring electrode. The first electrode 108 may be a continuous loop around a circumference of the semiconductor processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112 and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the semiconductor processing chamber 100. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

The first electrode 108 may be coupled with a first tuning circuit 128 that may control a ground pathway of the semiconductor processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132a. The second circuit leg may include a second inductor 132b coupled in series with the first electronic controller 134. The second inductor 132b may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with the surface 105 of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power. The substrate support 104 may also include one or more heating elements configured to heat the substrate to a processing temperature, which may be between about 25° C. and about 800° C. or greater.

The lid assembly 106 and substrate support 104 of FIG. 1 may be used with any processing chamber for plasma or thermal processing. In operation, the semiconductor processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the semiconductor processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132a and the second inductor 132b, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support 104. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support 104 may decline. The second electronic controller 140 may have a similar effect, increasing and decreasing aerial coverage of the plasma over the substrate support 104 as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

Processing chamber 100 may be utilized in some embodiments of the present technology for processing methods that may include gap filling materials for semiconductor structures intermittent inhibition and etching to maintain a seam-free and/or void-free gap fill. It is to be understood that the chamber described is not to be considered limiting, and any chamber that may be configured to perform operations as described may be similarly used. FIG. 2 shows exemplary operations in a processing method 200 according to some embodiments of the present technology. The method may be performed in a variety of processing chambers and on one or more mainframes or tools, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. Method 200 may describe operations shown schematically in FIGS. 3A-3E, the illustrations of which will be described in conjunction with the operations of method 200. It is to be understood that the figures illustrate only partial schematic views, and a substrate may contain any number of additional materials and features having a variety of characteristics and aspects as illustrated in the figures.

Method 200 may include additional operations prior to initiation of the listed operations. For example, additional processing operations may include forming structures on a substrate, which may include both forming and removing material. For example, transistor structures, memory structures, or any other structures may be formed. Prior processing operations may be performed in the chamber in which method 200 may be performed, or processing may be performed in one or more other processing chambers prior to delivering the substrate into the semiconductor processing chamber or chambers in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support, which may be a pedestal such as substrate support 104, and which may reside in a processing region of the chamber, such as processing volume 120 described above.

As illustrated in FIG. 3A, a substrate on which several operations have been performed may be substrate 305 of a structure 300, which may show a partial view of a substrate on which semiconductor processing may be performed. It is to be understood that structure 300 may show only a few top layers during processing to illustrate aspects of the present technology. The substrate 305 may include a material 310 in which one or more features 315 may be formed. Substrate 305 may be any number of materials used in semiconductor processing. The substrate material may be or include silicon, germanium, dielectric materials including silicon oxide or silicon nitride, metal materials, or any number of combinations of these materials, which may be the substrate 305, or materials formed in structure 300. Features 315 may be characterized by any shape or configuration according to the present technology. In some embodiments, the features 315 may be or include a trench structure or aperture formed within the substrate 305 or material 310.

Although the features 315 may be characterized by any shapes or sizes, in some embodiments the features 315 may be characterized by higher aspect ratios, or a ratio of a depth of the feature to a width across the feature. For example, in some embodiments, features 315 may be characterized by aspect ratios greater than or about 10:1, and may be characterized by aspect ratios greater than or about 25:1, greater than or about 30:1, greater than or about 35:1, greater than or about 40:1, greater than or about 45:1, greater than or about 50:1, greater than or about 60:1, greater than or about 70:1, greater than or about 80:1, greater than or about 90:1, greater than or about 100:1, greater than or about 110:1, greater than or about 120:1, greater than or about 130:1, greater than or about 140:1, greater than or about 150:1, greater than or about 175:1, greater than or about 200:1, or greater.

Additionally, the features 315 may be characterized by narrow widths or diameters across the feature including between two sidewalls, such as a dimension less than or about 250 nm, and may be characterized by a width across the feature of less than or about 200 nm, less than or about 150 nm, less than or about 100 nm, less than or about 90 nm, less than or about 80 nm, less than or about 70 nm, less than or about 60 nm, less than or about 50 nm, less than or about 40 nm, less than or about 30 nm, or less. Further, the features may be characterized by a depth of greater than or about 100 nm, and may be characterized by a depth of greater than or about 250 nm, greater than or about 500 nm, greater than or about 750 nm, greater than or about 1 μm, greater than or about 1.5 μm, greater than or about 2 μm, greater than or about 2.5 μm, greater than or about 3 μm, greater than or about 3.5 μm, greater than or about 4 μm, greater than or about 4.5 μm, greater than or about 5 μm, greater than or about 5.5 μm, or more.

Method 200 may gap filling materials for semiconductor structures. However, to reduce or eliminate the presence of a scam or a void in the gap fill material within the feature, which may occur in conventional atomic layer deposition (ALD) or plasma-enhanced ALD (PEALD) processes, method 200 may include inhibition and/or etching operations. As such, method 200 may include performing an inhibition operation prior to performing the gap filling. The inhibition operation of method 200 may include providing a nitrogen-containing precursor or other inhibition precursor to the processing region of the semiconductor processing chamber at operation 205. At optional operation 210, the inhibition operation of method 200 may include forming plasma effluents of the nitrogen-containing precursor. At operation 215, the inhibition operation of method 200 may include contacting the substrate 305 with the nitrogen-containing precursor or plasma effluents thereof. As illustrated in FIG. 3B, the contacting may form a nitrogen-containing material 312 on an upper portion of the one or more features 315.

Although any nitrogen-containing precursor may be used during the inhibition, in some embodiments, the nitrogen-containing precursor(s) may include, but are not limited to, diatomic nitrogen (N₂), ammonia (NH₃), as well as any other nitrogen-containing materials that may be used or useful in semiconductor processing. The nitrogen-containing precursor may be provided with one or more diluents or carrier gases such as an inert gas or other gas delivered with the nitrogen-containing precursor.

In embodiments, a flow rate of the nitrogen-containing precursor, or other inhibition precursor, may be selected to provide a desired amount of inhibition material 312. More specifically, at higher flow rates of the nitrogen-containing precursor, or other inhibition precursor, a greater amount of inhibition material 312 may be formed. In embodiments, the flow rate of the nitrogen-containing precursor, or other inhibition precursor, may be greater than or about 100 sccm, and may be greater than or about 250 sccm, greater than or about 500 sccm, greater than or about 750 sccm, greater than or about 1,000 sccm, greater than or about 1,500 sccm, greater than or about 2,000 sccm, greater than or about 3,000 sccm, greater than or about 4,000 sccm, or more. However, to balance the amount of inhibition material 312, such that the subsequent deposition may not be hindered by the inhibition material 312, the flow rate of the nitrogen-containing precursor, or other inhibition precursor, may be less than or about 4,000 sccm, and may be less than or about 3,000 sccm, less than or about 2,000 sccm, less than or about 1,500 sccm, less than or about 1,000 sccm, less than or about 750 sccm, less than or about 500 sccm, less than or about 250 sccm, less than or about 100 sccm, or less.

In subsequent cycles of method 200, the flow rate of the nitrogen-containing precursor, or other inhibition precursor, may be maintained. However, the flow rate of the nitrogen-containing precursor, or other inhibition precursor, may alternatively be reduced in subsequent cycles of operations 205-215 to reduce the amount of inhibition material 312 extending into the features 315. If the flow rate of the nitrogen-containing precursor, or other inhibition precursor, is not eventually reduced, the inhibition material 312 may begin to form on the previously deposited silicon-containing material 320, which may reduce or prevent additional deposition of silicon-containing material 320.

Some embodiments may include forming plasma effluents of the nitrogen-containing precursor, or other inhibition precursor, at optional operation 210. The plasma power applied during deposition may be a lower power plasma, which may reduce dissociation and control the amount of inhibition material 312 being formed. Accordingly, in some embodiments a plasma power source may deliver a plasma power to the faceplate, chamber, or substrate support of less than or about 5,000 W, and may deliver a power of less than or about 4,500 W, less than or about 4,000 W, less than or about 3,500 W, less than or about 3,000 W, less than or about 2,500 W, less than or about 2,000 W, less than or about 1,500 W, less than or about 1,000 W, less than or about 500 W, or less.

As previously discussed, contacting the substrate 305 with the nitrogen-containing precursor or plasma effluents thereof may form a nitrogen-containing material 312 on an upper portion of the one or more features 315. The inhibition may utilize ions of the nitrogen-containing precursor to poison an upper portion of the one or more features 315. This poisoning may reduce or prevent deposition of material in subsequent operations. However, since the inhibition utilizes ions of the nitrogen-containing precursor, which may have a shorter lifespan than radicals or other plasma constituents, the inhibition may only impact an upper portion of the features 315. For example, the upper portion of the features 315 impacted by the inhibition may be limited to less than or about 2 μm, and may be limited to less than or about 1.95 μm, less than or about 1.9 μm, less than or about 1.85 μm, less than or about 1.8 μm, less than or about 1.75 μm, less than or about 1.7 μm, or less. Therefore, in deeper features 315, the inhibition may not be able to poison a full length of the feature and inhibit deposition of material in subsequent operations. As further discussed below, the present technology may include a post-deposition etching operation to maintain a desired profile of the material being deposited in the features 315.

Subsequent to performing the inhibition operation at operations 205-215, method 200 may include performing a silicon-containing ALD process at operation 220. As illustrated in

FIG. 3C, the silicon-containing ALD process may deposit a silicon-containing material 320, such as silicon-and-oxygen-containing material, in the one or more features 315. The deposition may be performed in the same chamber as the inhibition, and may be performed in a cyclic process (with or without subsequent etching) to fill the feature 315.

The silicon-containing ALD or PEALD process may include a layer by layer deposition of silicon-containing material 320, which may be a silicon-and-oxygen-containing material. The silicon-containing ALD or PEALD may include a first precursor dose, such as a silicon-containing precursor dose or an oxygen-containing precursor dose. In silicon-containing PEALD processes, plasma effluents of the first precursor dose may be formed. The first precursor dose or, if formed, plasma effluents thereof may be adsorbed, such as through chemisorption, on the substrate 305 or material 310. In embodiments, the first precursor dose may deposit a silicon-containing material on the substrate 305. A first purge may be performed to remove excess amounts of the first precursor dose, such as the first precursor that has not been absorbed on the substrate 305 or material 310.

After the first purge, the silicon-containing ALD or PEALD may include a second precursor dose, such as a silicon-containing precursor dose or an oxygen-containing precursor (the opposite of the first precursor dose). In silicon-containing PEALD processes, plasma effluents of the second precursor dose may be formed. The second precursor or, if formed, plasma effluents thereof may react with the first precursor dose adsorbed on the substrate 305 or material 310. The reaction between the first precursor dose and the second precursor dose may form the silicon-containing material 320. In embodiments, the second precursor does may expose the silicon-containing material to an oxygen-containing precursor to convert the silicon-containing material to a silicon-and-oxygen-containing material. In other embodiments, the second precursor dose may be another material to form a different silicon-containing material. For example, the second precursor dose may utilize a carbon-containing precursor or a nitrogen-containing precursor to form a silicon-and-carbon-containing material or a silicon-and-nitrogen-containing material, respectively. A second purge may be performed to remove excess amounts of the second precursor dose, such as the second precursor that has not reacted with the first precursor to form silicon-containing material 320.

Although any silicon-containing precursor may be used, in some embodiments, the silicon-containing precursor(s) may be used during the silicon-containing ALD or PEALD process may include, but are not limited to, silane (SiH₄), disilane (Si₂H₆), trisilane (Si₃H₈), tetrasilane (Si₄H₁₀), pentasilane (Si₅H₁₂), or other organosilanes including cyclohexasilanes, an aminosilane, silicon tetrafluoride (SiF₄), silicon tetrachloride (SiCl₄), dichlorosilane (SiH₂Cl₂), tetraethyl orthosilicate (TEOS), as well as any other silicon-containing materials that may be used or useful in semiconductor processing. Similarly, although any oxygen-containing precursor may be used, in some embodiments, the oxygen-containing precursor(s) may be used during the silicon-containing ALD or PEALD process may include, but are not limited to, diatomic oxygen (O₂), nitrous oxide (N₂O), hydrogen peroxide (H₂O₂), or other oxygen-containing materials that may be used or useful in semiconductor processing.

If plasma-enhanced, a plasma power source may deliver a plasma power to the faceplate, chamber, or substrate support of greater than or about 250 W, and may deliver a power of greater than or about 500 W, greater than or about 1,000 W, greater than or about 1,500 W, greater than or about 2,000 W, greater than or about 2,500 W, greater than or about 3,000 W, greater than or about 3,500 W, greater than or about 4,000 W, greater than or about 4,500 W, greater than or about 5,000 W, greater than or about 5,500 W, greater than or about 6,000 W, greater than or about 7,000 W, greater than or about 8,000 W, or more.

After the second purge, the first precursor dose, first purge, and second precursor dose, and second purge may be repeated any number of times to continue forming silicon-containing material 320. The deposition may be conformal, and thus, growth may occur inward within the feature 315 from the walls defining the feature 315. The silicon-containing ALD or PEALD process may be performed for a period of time sufficient to produce an amount of coverage to at least partially fill the feature 315. As the feature 315 closes, a seam and/or a void may be formed. The seam and/or void may extend a portion or all of a distance of the feature 315 to an exposed upper surface as illustrated. The seam and/or void may be characterized by a number of shapes, which may include top-wide, bottom wide, as well as a more amorphous shape, as would be readily understood by the skilled artisan. To reduce or prevent the formation of the seam and/or void, method 200 may include an intermitted etch.

As previously discussed, subsequent an amount of deposition, in some embodiments of the present technology, an etching operation may be performed. The deposition may begin to pinch off the feature 315 including between sidewalls within the feature 315, and may produce seams and/or voids within the feature. While the inhibition may limit the amount of pinch off, the etch may maintain an opening of the feature 315. Accordingly, the etching may remove material causing the feature 315 to be pinched off and may allow for subsequent deposition to deposit material in regions that would have been seams and/or voids. The etching may be performed in the same chamber as the deposition and/or inhibition, and may be performed in a cyclic process (with or without the inhibition) to fill the feature 315. At operation 225, method 200 may include providing an etchant precursor to the processing region of the semiconductor processing chamber. At optional operation 230, the etching operation of method 200 may include forming plasma effluents of the etchant precursor. At operation 235, the etching operation of method 200 may include contacting the substrate with the etchant precursor or plasma effluents thereof. As illustrated in FIG. 3D, the contacting may etch a portion of the silicon-containing material from the upper portion of the one or more features 315.

Although any etchant precursor may be used during the etching, in some embodiments, the etchant precursor(s) may include, but are not limited to, a halogen-containing precursor, such as a chlorine-containing precursor and/or a fluorine-containing precursor. The etchant precursor may be provided with one or more additional precursors, such as a hydrogen-containing precursor, and/or diluents or carrier gases such as an inert gas or other gas delivered with the nitrogen-containing precursor.

In embodiments, a flow rate of the etchant precursor may be selected to provide a desired amount of etching. More specifically, at higher flow rates of the etchant precursor, an etch rate of the silicon-containing material 320 may increase. In embodiments, the flow rate of the etchant precursor may be greater than or about 10 sccm, and may be greater than or about 20 sccm, greater than or about 30 sccm, greater than or about 40 sccm, greater than or about 50 sccm, greater than or about 75 sccm, greater than or about 100 sccm, greater than or about 150 sccm, greater than or about 200 sccm, or more. However, to control the amount of etching, such that the silicon-containing material 320 may not be further removed than necessary or desired, the flow rate of the etchant precursor may be less than or about 200 sccm, and may be less than or about 150 sccm, less than or about 100 sccm, less than or about 75 sccm, less than or about 50 sccm, less than or about 40 sccm, less than or about 30 sccm, less than or about 20 sccm, less than or about 10 sccm, or less.

In subsequent cycles of method 200, the flow rate of the etchant precursor may be maintained. However, the flow rate of the etchant precursor may alternatively be reduced in subsequent cycles of operations 225-235 to reduce the amount of etching. If the flow rate of the etchant precursor is not eventually reduced, the etching may begin to remove too much silicon-containing material.

Some embodiments may include forming plasma effluents of the etchant precursor at optional operation 230. The plasma power applied during deposition may be a lower power plasma, which may reduce dissociation and control the amount of etching. Accordingly, in some embodiments a plasma power source may deliver a plasma power to the faceplate, chamber, or substrate support of less than or about 5,000 W, and may deliver a power of less than or about 4,500 W, less than or about 4,000 W, less than or about 3,500 W, less than or about 3,000 W, less than or about 2,500 W, less than or about 2,000 W, less than or about 1,500 W, less than or about 1,000 W, less than or about 500 W, less than or about 250 W, less than or about 200 W, less than or about 150 W, less than or about 100 W, less than or about 75 W, less than or about 50 W, or less.

Similar to the flow rate, in subsequent cycles of method 200, the plasma power provided to form plasma effluents of the etchant precursor may be maintained. However, the plasma power may alternatively be reduced in subsequent cycles of operations 225-235 to reduce dissociation and a resultant amount of etching.

Unlike the inhibition operation, the etching operation may utilize radicals to remove silicon-containing material 320. Having a longer lifetime than ions, the radicals of the etchant precursor may etch silicon-containing material 320 along a length of the features 315. However, it will be appreciated by those skilled in the art that the amount of etch will be higher at an upper portion of the silicon-containing material 320 due to a diffusion gradient as the etchant precursor travels to the bottom portion of the features 315. Therefore, an amount of etch may taper towards the bottom portion of the features 315. The amount of etching and/or degree of tapering may be tuned through a number of features, including etchant precursor flow rate, plasma power, bias power, and other processing conditions.

Some or all of the operations of method 200 may be repeated for a plurality of cycles. As illustrated in FIG. 3E, which may be after numerous cycles of method 200, the repetition may fill the features 315 with silicon-containing material 320 in a bottom-up and/or zipper-like fashion. By filling the features 315 in bottom-up and/or zipper-like fashion, the formation of seams and/or voids may be reduced or prevented entirely. As illustrated in FIG. 2, some cycles may include repeating the inhibition and deposition operations for a plurality of cycles. Other cycles may include repeating the deposition and etching operations for a plurality of cycles. Still other cycles may include repeating the inhibition, deposition, and etching operations for a plurality of cycles. It is contemplated that various cycles may be used and that any combination of operations may be used to fill the features 315 with silicon-containing material 320.

Temperature may impact operations of the present technology. For example, the silicon-containing ALD or PEALD process may be performed at a temperature less than or about 600° C., and may be performed at a temperature less than or about less than or about 575° C., less than or about 550° C., less than or about 525° C., less than or about 500° C., less than or about 475° C., less than or about 450° C., less than or about 425° C., less than or about 400° C., less than or about 375° C., less than or about 350° C., less than or about 325° C., less than or about 300° C., or less. Additionally, the method 200 may be performed at a temperature greater than or about 100° C., and may be performed at a temperature greater than or about 300° C., and may be performed at a temperature greater than or about 325° C., greater than or about 350° C., greater than or about 375° C., greater than or about 400° C., greater than or about 425° C., greater than or about 450° C., greater than or about 475° C., greater than or about 500° C., greater than or about 525° C., greater than or about 550° C., greater than or about 575° C., greater than or about 600° C., or more. The temperature may be maintained in any of these ranges throughout the silicon-containing ALD or PEALD process. To limit temperature adjustments in the semiconductor processing chamber, the inhibition and/or etching may also be performed at the same temperature or at a similar temperature to the silicon-containing ALD or PEALD process. However, it is also contemplated that temperature may be adjusted during operations of method 200.

Pressure may also impact operations of the present technology. For example, the silicon-containing ALD or PEALD process may be performed at a pressure less than or about 50 Torr, and may be performed at a pressure less than or about 40 Torr, less than or about 30 Torr, less than or about 20 Torr, less than or about 15 Torr, less than or about 10 Torr, less than or about 8 Torr, less than or about 6 Torr, less than or about 5 Torr, less than or about 4 Torr, less than or about 3 Torr, less than or about 2 Torr, less than or about 1 Torr, or less. Similarly to temperature, to limit pressure adjustments in the semiconductor processing chamber, the inhibition and/or etching may also be performed at the same pressure or at a similar pressure to the silicon-containing ALD or PEALD process. However, it is also contemplated that pressure may be adjusted during operations of method 200.

Due at least in part to the inhibition and/or etching, the present technology may form as-deposited silicon-containing material 320 characterized by a conformality of greater than or about 100%. Conformality may be measured by comparing deposition at a bottom portion of the features 315 compared to deposition at an upper portion of the features 315. In subsequent cycles of method 200, such as after an initial amount of silicon-containing material 320 is formed, the conformality may be measured based on an amount of newly-deposited silicon-containing material 320. In embodiments, the as-deposited silicon-containing material 320 may be characterized by a conformality of greater than or about 120%, and may be characterized by a conformality of greater than or about 125%, greater than or about 130%, greater than or about 135%, greater than or about 140%, greater than or about 145%, greater than or about 150%, or more.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a nitrogen-containing precursor” includes a plurality of such precursors, and reference to “the silicon-containing material” includes reference to one or more materials and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
i) performing an inhibition operation on a substrate disposed within a processing region of a semiconductor processing chamber, wherein the substrate defines one or more features characterized by an aspect ratio of greater than or about 30:1;
ii) performing a silicon-containing atomic layer deposition (ALD) process, wherein the silicon-containing ALD process deposits a silicon-containing material in the one or more features;
iii) etching a portion of the silicon-containing material from an upper portion of the one or more features; and
iv) repeating operations i through iii for a plurality of cycles.

2. The semiconductor processing method of claim 1, wherein the one or more features are characterized by a width of less than or about 250 nm.

3. The semiconductor processing method of claim 1, wherein the one or more features are characterized by a depth of greater than or about 1 μm.

4. The semiconductor processing method of claim 1, wherein the one or more features are characterized by an aspect ratio of greater than or about 100:1.

5. The semiconductor processing method of claim 1, wherein the inhibition operation comprises contacting the substrate with a nitrogen-containing precursor.

6. The semiconductor processing method of claim 5, wherein the nitrogen-containing precursor comprises ammonia (NH₃).

7. The semiconductor processing method of claim 5, further comprising: forming plasma effluents of the nitrogen-containing precursor.

8. The semiconductor processing method of claim 1, wherein the inhibition operation reduces deposition of silicon-containing material at an upper portion of the one or more features.

9. The semiconductor processing method of claim 1, wherein the silicon-containing ALD process comprises:
ii-a) depositing a silicon-containing material on the substrate;
ii-b) purging the processing region after operation ii-a;
ii-c) exposing the silicon-containing material to an oxygen-containing precursor to convert the silicon-containing material to a silicon-and-oxygen-containing material; and ii-d) purging the processing region after operation ii-c.

10. The semiconductor processing method of claim 1, wherein the silicon-containing ALD process is plasma-enhanced.

11. The semiconductor processing method of claim 1, wherein the etching prevents closing of the one or more features.

12. The semiconductor processing method of claim 1, wherein the silicon-containing material is seam-free and void-free.

13. The semiconductor processing method of claim 1, wherein the as-deposited silicon-containing material is characterized by a conformality of greater than or about 120%.

14. A semiconductor processing method comprising:
providing a nitrogen-containing precursor to a processing region of a semiconductor processing chamber, wherein a substrate is housed within the processing region, and wherein the substrate defines one or more features characterized by an aspect ratio of greater than or about 30:1;
contacting the substrate with the nitrogen-containing precursor, wherein the contacting forms a nitrogen-containing material on an upper portion of the one or more features; performing a silicon-containing atomic layer deposition (ALD) process, wherein the silicon-containing ALD process deposits a silicon-containing material in the one or more features;
providing an etchant precursor to the processing region;
contacting the substrate with the etchant precursor, wherein the contacting etches a portion of the silicon-containing material from the upper portion of the one or more features.

15. The semiconductor processing method of claim 14, wherein the nitrogen-containing precursor comprises ammonia (NH₃).

16. The semiconductor processing method of claim 14, wherein the etchant precursor comprises a fluorine-containing precursor.

17. The semiconductor processing method of claim 14, further comprising:
forming plasma effluents of the etchant precursor.

18. The semiconductor processing method of claim 14, further comprising:
repeating the performing the silicon-containing ALD process, the contacting the substrate with the etchant precursor, and optionally the contacting the substrate with the nitrogen-containing precursor for a plurality of cycles.

19. A semiconductor processing method comprising:
providing a nitrogen-containing precursor to a processing region of a semiconductor processing chamber, wherein a substrate is housed within the processing region, and wherein the substrate defines one or more features characterized by an aspect ratio of greater than or about 30:1;
forming plasma effluents of the nitrogen-containing precursor;
contacting the substrate with the plasma effluents of the nitrogen-containing precursor, wherein the contacting forms a nitrogen-containing material on an upper portion of the one or more features;
performing a silicon-containing atomic layer deposition (ALD) process, wherein the silicon-containing ALD process comprises:
depositing a silicon-containing material on the substrate;
purging the processing region;
exposing the silicon-containing material to an oxygen-containing precursor to convert the silicon-containing material to a silicon-and-oxygen-containing material; and
purging the processing region;
providing an etchant precursor to the processing region;
contacting the substrate with the etchant precursor, wherein the contacting etches a portion of the silicon-containing material from the upper portion of the one or more features.

20. The semiconductor processing method of claim 19, wherein the nitrogen-containing precursor comprises ammonia (NH₃).
